(19) United States
(12) Patent Application Publication
(10) Pub. No.: US 2026/0282632 A1
(43) Pub. Date: Sep. 17, 2026

(54) DISPLAY DEVICE, METHOD OF MANUFACTURING THE SAME, AND ELECTRONIC DEVICE INCLUDING THE SAME

(71) Applicant: Samsung Display Co., Ltd., Yongin-si (KR)

(72) Inventor: Chungi YOU, Yongin-si (KR)

(73) Assignee: Samsung Display Co., Ltd., Yongin-si (KR)

(21) Appl. No.: 19/416,544

(22) Filed: Dec. 11, 2025

(30) Foreign Application Priority Data
Jan. 13, 2025 (KR) 10-2025-0004797

(51) Int. Cl. H10H 29/39; H10H 29/01; H10H 29/37; H10H 29/41; H10H 29/49; H10K 59/12; H10K 59/122; H10K 59/123; H10K 59/124; H10K 59/131

(52) U.S. Cl. CPC H10H 29/39; H10H 29/012; H10H 29/37; H10H 29/41; H10H 29/49; H10K 59/1201; H10K 59/122; H10K 59/123; H10K 59/124; H10K 59/131

(57) ABSTRACT

A display device is provided. The display device includes: a transistor array substrate display and non-display areas; a pixel electrode in an emission area on the transistor array substrate, wherein the pixel electrode includes: a first layer connected to a pixel circuit and including a first conductive material; a second layer on the first layer and including a second conductive material; a third layer on the second layer, wherein the third layer includes a third conductive material, wherein the third layer is on an upper surface of an edge portion of the second layer, and wherein an opening that exposes an upper surface of a central portion of the second layer is defined in the third layer; and a fourth layer on the second layer and the third layer and including a fourth conductive material; an emission layer on the pixel electrode; and a common electrode on the emission layer.

This application claims priority to Korean Patent Application No. 10-2025-0004797, filed on Jan. 13, 2025, in the Korean Intellectual Property Office, the disclosure of which is incorporated by reference herein in its entirety.

### BACKGROUND

### Field

The present disclosure relates to a display device, a method of manufacturing the same, and an electronic device including the same. More particularly, the present disclosure relates to a micro light emitting diode display device, a method of manufacturing the same, and an electronic device including the same.

### Description of Related Art

Recently, a head mounted display (“HMD”) including a display device has been developed. The HMD is a glasses-type monitor device which may be used in virtual reality (“VR”) or augmented reality (“AR”) applications, and may be worn in the form of glasses, a helmet, or the like. The HMD may focus near the user's eyes. The HMD may provide an image displayed on a display device to the user's eyes through a lens.

The HMD may include a high-resolution micro light emitting diode display device. The high-resolution micro light emitting diode display device may be an organic light emitting diode on silicon (OLEDOS) formed using a silicon wafer-based semiconductor process.

### SUMMARY

One or more embodiments provide a display device with improved display quality and reliability.

One or more embodiments also provide a method of manufacturing a display device with improved display quality and reliability.

One or more embodiments also provide an electronic device with improved display quality and reliability.

Additional features of the inventive concepts will be set forth in the description which follows, and in part will be apparent from the description, or may be learned by practice of embodiments.

According to an aspect of an embodiment, a display device includes: a transistor array substrate including a display area and a non-display area outside the display area, wherein the display area includes an emission area and a non-emission area, and the transistor array substrate includes a pixel circuit in the display area; a pixel electrode in the emission area on the transistor array substrate, wherein the pixel electrode includes: a first layer connected to the pixel circuit and including a first conductive material; a second layer on the first layer and including a second conductive material; a third layer on the second layer, wherein the third layer includes a third conductive material, wherein the third layer is on an upper surface of an edge portion of the second layer, and wherein an opening that exposes an upper surface of a central portion of the second layer is defined in the third layer; and a fourth layer on the second layer and the third layer and including a fourth conductive material; an emission layer on the pixel electrode; and a common electrode on the emission layer.

The second to fourth conductive materials may be different from each other.

The second conductive material may have a light reflecting characteristic, and the fourth conductive material may have a light transmitting characteristic.

A light reflectance of the third conductive material may be less than a light reflectance of the second conductive material.

The fourth layer may contact a side surface of the first layer, a side surface of the second layer, and a side surface of the third layer.

The fourth layer may contact an upper surface of the third layer and the upper surface of the central portion of the second layer exposed by the opening of the third layer.

The second conductive material may include a metal or an alloy, the third conductive material may include a metal nitride, and the fourth conductive material may include a transparent conductive oxide.

The second conductive material may include aluminum or an aluminum alloy, the third conductive material may include titanium nitride, and the fourth conductive material may include indium tin oxide.

The third layer may include an inner side surface defining the opening and an outer side surface opposite to the inner side surface, and the fourth layer may contact the inner side surface of the third layer and the outer side surface of the third layer.

The side surface of the first layer, the side surface of the second layer, and the outer side surface of the third layer may be coplanar.

The emission layer may include a lower emission layer, a charge generation layer, and an upper emission layer that are sequentially stacked, the emission area may be one among a plurality of emission areas, and the charge generation layers respectively in the plurality of emission areas may be separated from each other.

The common electrode may have a light transmitting characteristic, and in the plurality of emission areas, a distance between the second layer of the pixel electrode and the common electrode may be constant.

The display device may further include: a pixel defining layer defining first emission openings respectively corresponding to the plurality of emission areas; and a separator structure on the pixel defining layer, defining second emission openings respectively corresponding to the plurality of emission areas, and separating the charge generation layers respectively in the plurality of emission areas from each other.

The separator structure may include a first insulating layer, a second insulating layer, and a third insulating layer that are sequentially stacked, and the separator structure may have an undercut structure in which a width of the second insulating layer is less than a width of the third insulating layer in the display area.

In the display area, a side surface of the third insulating layer defining one of the second emission openings may protrude from a side surface of the second insulating layer defining one of the second emission openings toward a center of the one of the second emission openings.

The display device may further include: a common voltage supply line in the non-display area; and a connection electrode in the non-display area. The connection electrode may include: a first connection layer connected to the common voltage supply line and including the first conductive material; a second connection layer on the first connection layer and including the second conductive material; a third connection layer on the second connection layer, wherein the third connection layer includes the third conductive material, and covers an entire upper surface of the second connection layer; and a fourth connection layer on the third connection layer and including the fourth conductive material.

The pixel defining layer may define a first connection opening on the connection electrode in the non-display area, the separator structure may define a second connection opening on the connection electrode in the non-display area, and the common electrode may be connected to the connection electrode in the non-display area through the first connection opening and the second connection opening.

In the non-display area, a side surface of the second insulating layer defining the second connection opening may protrude from a side surface of the third insulating layer defining the second connection opening toward a center of the second connection opening.

According to another aspect of an embodiment, a method of manufacturing a display device, includes: providing a transistor array substrate including a display area including an emission area and a non-emission area and a non-display area outside the display area, the transistor array substrate including a pixel circuit in the display area; sequentially forming a first conductive layer, a second conductive layer, and a third conductive layer on the transistor array substrate; partially etching the third conductive layer to form an opening corresponding to the emission area; forming a first layer corresponding to the emission area, a second layer on the first layer, and a third layer covering an upper surface of an edge portion of the second layer by partially etching each of the first conductive layer and the second conductive layer, wherein the third layer defines an opening in the emission area that exposes an upper surface of a central portion of the second layer; forming a fourth layer on the second and third layers to form a pixel electrode including the first to fourth layers; forming an emission layer on the pixel electrode; and forming a common electrode on the emission layer.

According to another aspect of an embodiment, an electronic device includes: a display device configured to display an image; and a processor configured to provide input image data and an input control signal to the display device. The display device includes: a transistor array substrate including a display area and a non-display area outside the display area, wherein the display area includes an emission area and a non-emission area, and the transistor array substrate includes a pixel circuit in the display area; a pixel electrode in the emission area on the transistor array substrate, wherein the pixel electrode includes: a first layer connected to the pixel circuit and including a first conductive material; a second layer on the first layer and including a second conductive material; a third layer on the second layer, wherein the third layer includes a third conductive material, wherein the third layer is on an upper surface of an edge portion of the second layer, and wherein an opening that exposes an upper surface of a central portion of the second layer is defined in the third layer; and a fourth layer on the second layer and the third layer and including a fourth conductive material; an emission layer on the pixel electrode; and a common electrode on the emission layer.

According to one or more embodiments, variations in display quality depending on a viewing angle may be reduced, and thus the display quality of the display device may be improved. In addition, the connection failure between the pixel circuit and the transparent electrode of the pixel electrode may be prevented or reduced, and thus the reliability and yield of the display device may be improved.

It is to be understood that both the foregoing general description and the following detailed description are exemplary and explanatory and are intended to provide further explanation of the invention as claimed.

### BRIEF DESCRIPTION OF DRAWINGS

The above and other aspects will be more apparent from the following description of embodiments taken in conjunction with the accompanying drawings.

FIG. 1 is a plan view illustrating a display device according to an embodiment.

FIG. 2 is a cross-sectional view taken along line I-I’ of FIG. 1.

FIG. 3 is an enlarged cross-sectional view illustrating an area A of FIG. 2.

FIG. 4 is a cross-sectional view taken along line II-II’ of FIG. 1.

FIGS. 5-16 are cross-sectional views illustrating a method of manufacturing a display device according to an embodiment.

FIG. 17 is a block diagram illustrating an electronic device according to an embodiment.

FIG. 18 are schematic diagrams illustrating an electronic device according to various embodiments.

### DETAILED DESCRIPTION

Various example embodiments will be described more fully hereinafter with reference to the accompanying drawings, in which some example embodiments are shown. The present inventive concept may be embodied in many different forms and should not be construed as limited to example embodiments set forth herein. Rather, these example embodiments are provided so that this disclosure will be thorough and complete, and will fully convey the scope of the present inventive concept to those skilled in the art. Each embodiment provided in the following description is not excluded from being associated with one or more features of another example or another embodiment also provided herein or not provided herein but consistent with the present disclosure. In the drawings, the sizes and relative sizes of layers and regions may be exaggerated for clarity.

In the disclosure, various modifications can be made, various forms can be used, and specific embodiments will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third etc., may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “on,” “connected” or “coupled” to another element, it can be directly on, connected or coupled to the other element or intervening element(s) may be present. In contrast, when an element is referred to as being “directly on,” “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. The same reference numerals are used for the same components in the drawings, and redundant descriptions of the same components will be omitted.

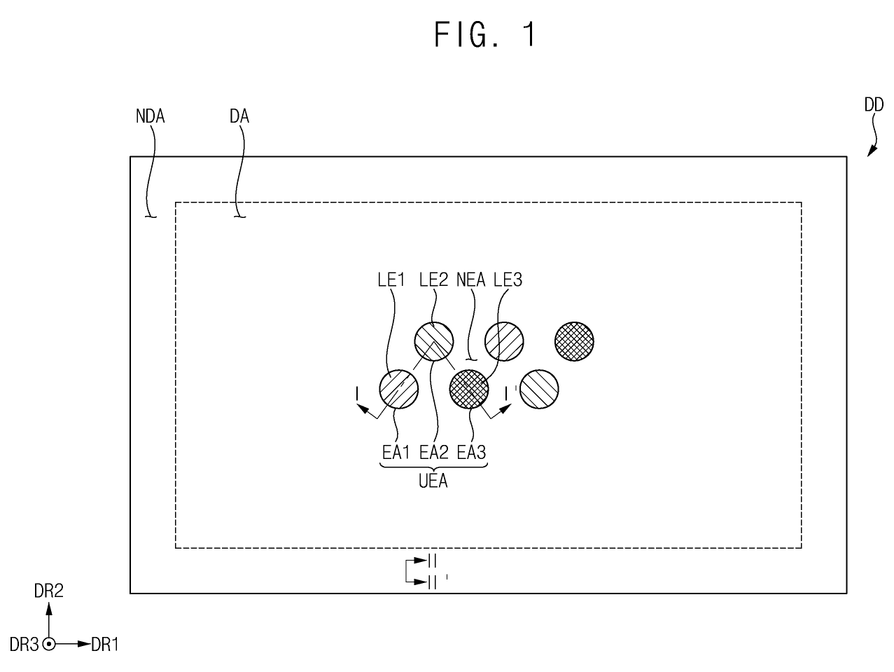

FIG. 1 is a plan view illustrating a display device according to an embodiment.

Referring to FIG. 1, in an embodiment, a display device DD may display an image through a display surface, which is extends along a first direction DR1 and a second direction DR2 crossing the first direction DR1, in a third direction DR3. For example, the second direction DR2 may be perpendicular to the first direction DR1. The third direction DR3 may be substantially parallel to a normal direction of the display surface. The display surface may correspond to an upper surface (or a front surface) of the display device DD.

The display device DD may include a display area DA and a non-display area NDA. The display area DA may be an area that displays the image (i.e., an area through which light is emitted by the display device DD). A plurality of light emitting elements for generating the image may be disposed in the display area DA.

In an embodiment, the display device DD may be a micro light emitting diode display device including micro light emitting diodes as the light emitting elements. However, example embodiments are not limited thereto, and the display device DD may be an organic light emitting diode display device including organic light emitting diodes as the light emitting elements.

The display area DA may include first to third emission areas EA1, EA2, and EA3 and a non-emission area NEA. Each of the first to third emission areas EA1, EA2, and EA3 may be an area where the light emitting element is disposed to emit light. A first light emitting element LE1 may be disposed in the first emission area EA1, a second light emitting element LE2 may be disposed in the second emission area EA2, and a third light emitting element LE3 may be disposed in the third emission area EA3.

The first to third emission areas EA1, EA2, and EA3 may emit light of different colors. For example, the first emission area EA1 may emit red light, the second emission area EA2 may emit green light, and the third emission area EA3 may emit blue light. However, example embodiments are not limited thereto. In an embodiment, the first to third emission areas EA1, EA2, and EA3 adjacent to each other may form one unit emission area UEA. A plurality of unit emission areas UEA may be repeatedly disposed in the display area DA.

In an embodiment, the first to third light emitting elements LE1, LE2, and LE3 may emit light of different colors. For example, the first light emitting element LE1 may emit red light, the second light emitting element LE2 may emit green light, and the third light emitting element LE3 may emit blue light. The first light emitting area EA1 may emit red light emitted from the first light emitting element LE1, the second light emitting area EA2 may emit green light emitted from the second light emitting element LE2, and the third light emitting area EA3 may emit blue light emitted from the third light emitting element LE3.

In another embodiment, the first to third light emitting elements LE1, LE2, and LE3 may emit light of the same color. For example, the first to third light emitting elements LE1, LE2, and LE3 may emit white light. Color filters for selectively transmitting light of a specific color (i.e., light of a specific wavelength band) of the white light may be disposed in the first to third emission areas EA1, EA2, and EA3, respectively. For example, a red color filter that selectively transmits red light may be disposed in the first emission area EA1. The first emission area EA1 may emit red light by filtering the white light emitted from the first light emitting element LE1. A green color filter that selectively transmits green light may be disposed in the second emission area EA2. The second emission area EA2 may emit green light by filtering the white light emitted from the second light emitting element LE2. A blue color filter that selectively transmits blue light may be disposed in the third emission area EA3. The third emission area EA3 may emit blue light by filtering the white light emitted from the third light emitting element LE3.

In an embodiment, in a plan view, the first to third emission areas EA1, EA2, and EA3 may have different sizes. For example, the size of the second emission area EA2 may be greater than the size of the first emission area EA1, and the size of the third emission area EA3 may be greater than the size of the second emission area EA2, but example embodiments are not limited thereto. In another embodiment, in a plan view, the first to third emission areas EA1, EA2, and EA3 may have substantially the same size.

In an embodiment, each of the first to third emission areas EA1, EA2, and EA3 may have a circular planar shape. In this case, variations in display quality depending on a viewing angle may be reduced. However, this is exemplary and example embodiments are not limited thereto, and each of the first to third emission areas EA1, EA2, and EA3 may have a polygonal, elliptical, or irregular planar shape.

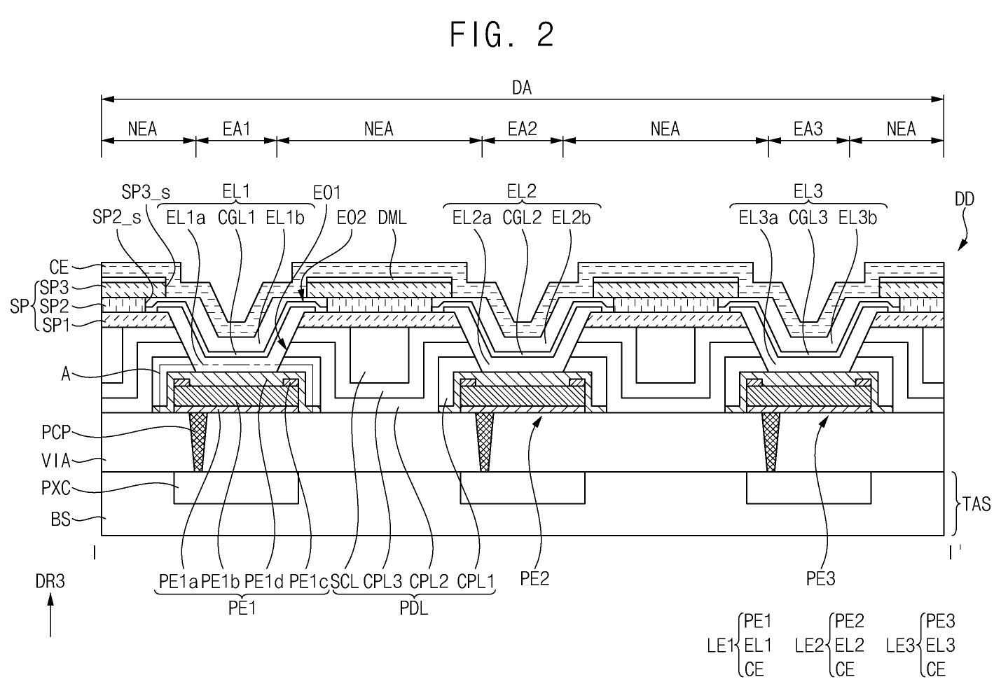

The non-emission area NEA may be an area in the display area DA that does not emit light. The first to third emission areas EA1, EA2, and EA3 may be defined by a pixel defining layer (PDL of FIG. 2) disposed in the non-emission area NEA. In a plan view, the non-emission area NEA may surround each of the first to third emission areas EA1, EA2, and EA3. In a plan view, the non-emission area NEA may be positioned between the first to third emission areas EEA1, EA2, and EA3 adjacent to each other.

In an embodiment, in a plan view, the non-emission area NEA may have a relatively large width. That is, the first to third emission areas EA1, EA2, and EA3 adjacent to each other may be spaced apart from each other by a relatively large distance. Accordingly, a color mixing depending on the viewing angle may be reduced.

The non-display area NDA may be an area that does not display the image. The non-display area NDA may be positioned around the display area DA. The non-display area NDA may be positioned outside the display area DA. For example, the non-display area NDA may surround the display area DA in a plan view. Drivers and wirings for driving the display area DA may be disposed in the non-display area NDA.

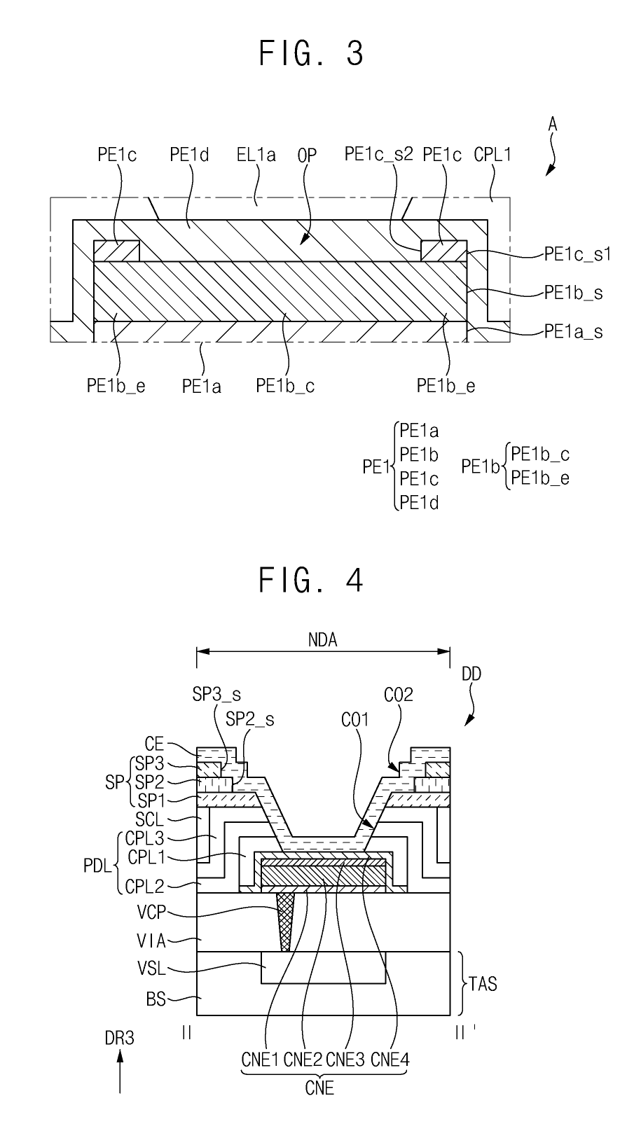

FIG. 2 is a cross-sectional view taken along line I-I’ of FIG. 1. FIG. 3 is an enlarged cross-sectional view illustrating an area A of FIG. 2.

Referring to FIGS. 1-3, in an embodiment, the display device DD may include a transistor array substrate TAS, a via insulating layer VIA, pixel connection patterns PCP, the first to third light emitting elements LE1, LE2, and LE3, the pixel defining layer PDL, and a separator (or separator structure) SP. The first light emitting element LE1 may include a first pixel electrode PE1, a first emission layer EL1, and a common electrode CE. The second light emitting element LE2 may include a second pixel electrode PE2, a second emission layer EL2, and the common electrode CE. The third light emitting element LE3 may include a third pixel electrode PE3, a third emission layer EL3, and the common electrode CE.

The transistor array substrate TAS may include a base substrate BS and pixel circuits PXC.

The base substrate BS may include the display area DA and the non-display area NDA. The display area DA may include the first to third emission areas EA1, EA2, and EA3 and the non-emission area NEA.

In an embodiment, the base substrate BS may be a semiconductor substrate. For example, the base substrate BS may include silicon, germanium, or silicon/germanium, or may be a silicon on isolation (“SOI”) substrate. The base substrate BS may support other components of the display device DD.

The pixel circuits PXC may be disposed in the display area DA. The pixel circuits PXC may be electrically connected to the first to third light emitting elements LE1, LE2, and LE3, respectively. Each of the pixel circuits PXC may include various driving elements (e.g., at least one thin film transistor, at least one capacitor, or the like) and wirings (e.g., a gate line, a data line, a power transmission line, or the like) for driving corresponding one of the light emitting elements.

The via insulation layer VIA may be disposed on the transistor array substrate TAS. For example, the via insulation layer VIA may include an organic insulating material.

In an embodiment, first through holes that penetrate the via insulation layer VIA in the third direction DR3 may be defined in the via insulation layer VIA in the display area DA. The first through holes may correspond to the pixel circuits PXC, respectively.

The pixel connection patterns PCP may be respectively disposed in the first through holes of the via insulating layer VIA in the display area DA. Each of the pixel connection patterns PCP may be electrically connected to corresponding one of the pixel circuits PXC. Each of the pixel connection patterns PCP may include a conductive material, such as tungsten (W).

The first to third pixel electrodes PE1, PE2, and PE3 may be disposed on the via insulating layer VIA. The first to third pixel electrodes PE1, PE2, and PE3 may be disposed to respectively correspond to the first to third emission areas EA1, EA2, and EA3. The first to third pixel electrodes PE1, PE2, and PE3 may be spaced apart from each other. Each of the first to third pixel electrodes PE1, PE2, and PE3 may be electrically connected to corresponding one of the pixel circuits PXC through corresponding one of the pixel connection patterns PCP.

Each of the first to third pixel electrodes PE1, PE2, and PE3 may have a multi-layer structure. In an embodiment, the first to third pixel electrodes PE1, PE2, and PE3 may have substantially the same structure.

In an embodiment, the first pixel electrode PE1 may include a first layer PE1a, a second layer PE1b, a third layer PE1c, and a fourth layer PE1d.

The first layer PE1a may be disposed on the via insulating layer VIA. The first layer PE1a may be electrically connected to the corresponding one of the pixel circuits PXC through the corresponding one of the pixel connection patterns PCP. For example, a lower surface of the first layer PE1a may contact an upper surface of the corresponding one of the pixel connection patterns PCP. For example, the lower surface of the first layer PE1a may directly contact the upper surface of the corresponding one of the pixel connection patterns PCP.

The first layer PE1a may include a first conductive material. In an embodiment, the first conductive material may include a metal or an alloy. For example, the first conductive material may include (or may be) titanium (Ti), but example embodiments are not limited thereto.

The second layer PE1b may be disposed on the first layer PE1a. For example, the second layer PE1b may be disposed directly on the first layer PE1a. For example, a lower surface of the second layer PE1b may contact an entire upper surface of the first layer PE1a. For example, the lower surface of the second layer PE1b may directly contact the entire upper surface of the first layer PE1a.

The second layer PE1b may include a central portion PE1b_c and an edge portion PE1b_eoutside the central portion PE1b_c. The edge portion PE1b_e may be a portion surrounding the central portion PE1b_c in a plan view. In an embodiment, the central portion PE1b_c may be positioned in the first emission area EA1, and the edge portion PE1b_emay be positioned in the non-emission area NEA outside the first emission area EA1.

The second layer PE1b may include a second conductive material. The second conductive material may be different from the first conductive material. The second conductive material may have a light reflecting characteristic. The second layer PE1b may be a reflective electrode. In an embodiment, the second conductive material may include a metal or an alloy. For example, the second conductive material may include (or may be) aluminum (Al) or an aluminum alloy (e.g., an aluminum-copper alloy), but example embodiments are not limited thereto.

The third layer PE1c may be disposed on the second layer PE1b. For example, the third layer PE1c may be disposed directly on the second layer PE1b.

The third layer PE1c may include a third conductive material. The third conductive material may be different from the second conductive material. A light reflectance of the third conductive material may be less than a light reflectance of the second conductive material. In an embodiment, the third conductive material may include a metal nitride. The third conductive material may not include a metal oxide. For example, the third conductive material may include (or may be) titanium nitride (TiNₓ), but example embodiments are not limited thereto.

In some embodiments, the third conductive material and the first conductive material may be same. For example, the first conductive material and the third conductive material may include (or may be) TiNₓ, but example embodiments are not limited thereto.

The third layer PE1c may be disposed on the edge portion PE1b_e of the second layer PE1b, and may not be disposed on the central portion PE1b_c of the second layer PE1b. The third layer PE1c may cover an upper surface of the edge portion PE1b_e of the second layer PE1b. The third layer PE1c may define an opening OP that exposes an upper surface of the central portion PE1b_c of the second layer PE1b. For example, the third layer PE1c may have a ring shape in a plan view.

As illustrated in FIG. 3, the third layer PE1c may include an inner side surface PE1c_s2 defining the opening OP and an outer side surface PE1c_s1 opposite to the inner side surface PE1c_s2. In an embodiment, a side surface PE1a_s of the first layer PE1a, a side surface PE1b_s of the second layer PE1b, and the outer side surface PE1c_s1 of the third layer PE1c may be aligned with each other. For example, the side surface PE1a_s of the first layer PE1a, the side surface PE1b_s of the second layer PE1b, and the outer side surface PE1c_s1 of the third layer PE1cmay be coplanar.

The fourth layer PE1d may be disposed on the second layer PE1b and the third layer PE1c. For example, the fourth layer PE1d may be disposed directly on the third layer PE1c.

The fourth layer PE1d may include a fourth conductive material. The fourth conductive material may be different from the first to third conductive materials. The fourth conductive material may have a light transmitting characteristic. The fourth layer PE1d may be a transparent electrode. In an embodiment, the fourth conductive material may include a transparent conductive oxide. For example, the fourth conductive material may include (or may be) indium tin oxide (ITO), indium zinc oxide (IZO), zinc oxide (ZnOₓ), indium oxide (InOₓ), indium gallium oxide (IGO), aluminum zinc oxide (AZO), or the like, but example embodiments are not limited thereto.

In an embodiment, the fourth layer PE1d may entirely cover a structure in which the first layer PE1a, the second layer PE1b, and the third layer PE1c are stacked. The fourth layer PE1d may contact the side surface PE1a_s of the first layer PE1a, the side surface PE1b_s of the second layer PE1b, and the outer side surface PE1c_s1 of the third layer PE1c. For example, the fourth layer PE1d may directly contact the side surface PE1a_s of the first layer PE1a, the side surface PE1b_s of the second layer PE1b, and the outer side surface PE1c_s1 of the third layer PE1c. The fourth layer PE1d may contact an upper surface of the third layer PE1c, the inner side surface PE1c_s2 of the third layer PE1c defining the opening OP, and the upper surface of the central portion PE1b_c of the second layer PE1b exposed by the opening OP of the third layer PE1c. For example, the fourth layer PE1d may directly contact the upper surface of the third layer PE1c, the inner side surface PE1c_s2 of the third layer PE1c defining the opening OP, and the upper surface of the central portion PE1b_c of the second layer PE1b exposed by the opening OP of the third layer PE1c.

As described above, the second layer PE1b may include aluminum or an aluminum alloy to function as the reflective electrode, and the fourth layer PE1d may include a transparent conductive oxide to function as the transparent electrode. Accordingly, at a portion where the second layer PE1b and the fourth layer PE1d contact, aluminum of the second layer PE1b may be oxidized. The oxidized aluminum of the second layer PE1b may form an insulating aluminum oxide (AlOₓ) film may be formed on a surface of the second layer PE1b. Accordingly, in order to electrically connect the fourth layer PE1d and the first layer PE1a electrically connected to the pixel circuit PXC, the fourth layer PE1d may be formed to contact the side surface PE1a_s of the first layer PE1a.

If the third layer PE1c is not disposed on the edge portion PE1b_e of the second layer PE1b, the fourth layer PE1d may not contact the side surface PE1a_s of the first layer PE1a due to processing reasons or the like, and thus the fourth layer PE1d may not be electrically connected to the first layer PE1a. In this case, the fourth layer PE1d may not be electrically connected to the corresponding one of the pixel circuits PXC, resulting in a defect in which the first light emitting element LE1 does not emit light.

However, according to embodiments, the third layer PE1c including a conductive material but not a metal oxide may be disposed on the edge portion PE1b_e of the second layer PE1b. At a portion where the second layer PE1b and the third layer PE1c contact, an insulating AlOₓ film may not be formed on a surface of the second layer PE1b, so that the third layer PE1c may be electrically connected to the second layer PE1b. Accordingly, even when the fourth layer PE1d does not contact the side surface PE1a_s of the first layer PE1a, the fourth layer PE1d may be electrically connected to the first layer PE1a through the third layer PE1c and the second layer PE1b. Accordingly, the reliability and yield of the display device DD may be improved.

In addition, because the third layer PE1c is not disposed on the central portion PE1b_c of the second layer PE1b but only on the edge portion PE1b_e of the second layer PE1b, the function of the second layer PE1b as the reflective electrode may not be reduced. Accordingly, the light efficiency of the display device DD may be prevented from being reduced.

In an embodiment, the first to third pixel electrodes PE1, PE2, and PE3 may have substantially the same structure as each other. The first to third pixel electrodes PE1, PE2, and PE3 may have substantially the same thickness as each other. That is, a distance between a lower surface of the first layer and an upper surface of the fourth layer of each of the first to third pixel electrodes PE1, PE2, and PE3 may be constant. Each of the first to third light emitting elements LE1, LE2, and LE3 may have a non-resonant structure. The description about the first pixel electrode PE1 described above may be substantially equally applied to the second and third pixel electrodes PE2 and PE3.

The pixel defining layer PDL may be disposed on the via insulating layer VIA and the first to third pixel electrodes PE1, PE2, and PE3. The pixel defining layer PDL may be disposed in the non-emission area NEA. As illustrated in FIG. 2, the pixel defining layer PDL may cover an edge portion of each of the first to third pixel electrodes PE1, PE2, and PE3, and may define first emission openings EO1 that respectively expose central portions of the first to third pixel electrodes PE1, PE2, and PE3. The first emission openings EO1 may respectively correspond to the first to third emission areas EA1, EA2, and EA3. That is, the first to third emission areas EA1, EA2, and EA3 may be defined by the first emission openings EO1 of the pixel defining layer PDL.

In an embodiment, the pixel defining layer PDL may include a first capping layer CPL1, a second capping layer CPL2, a third capping layer CPL3, and a step compensation layer SCL.

The first capping layer CPL1 may be disposed on the first to third pixel electrodes PE1, PE2, and PE3. In an embodiment, as illustrated in FIG. 2, the first capping layer CPL1 may be provided as a plurality of first capping layers CPL1 that are disposed respectively corresponding to the first to third pixel electrodes PE1, PE2, and PE3 and are spaced apart from each other.

In an embodiment, the first capping layer CPL1 may include an inorganic insulating material. For example, the first capping layer CPL1 may include silicon oxide (SiOₓ), but example embodiments are not limited thereto.

The second capping layer CPL2 may be disposed on the first capping layer CPL1. In an embodiment, the second capping layer CPL2 may be entirely disposed on the via insulation layer VIA to cover the plurality of first capping layers CPL1.

In an embodiment, the second capping layer CPL2 may include an inorganic insulating material. For example, the second capping layer CPL2 may include the same material as the first capping layer CPL1. For example, the second capping layer CPL2 may include SiOₓ, but example embodiments are not limited thereto. In an embodiment, the first capping layer CPL1 or the second capping layer CPL2 may be omitted.

The third capping layer CPL3 may be disposed on the second capping layer CPL2. In an embodiment, the third capping layer CPL3 may be entirely disposed on the second capping layer CPL2.

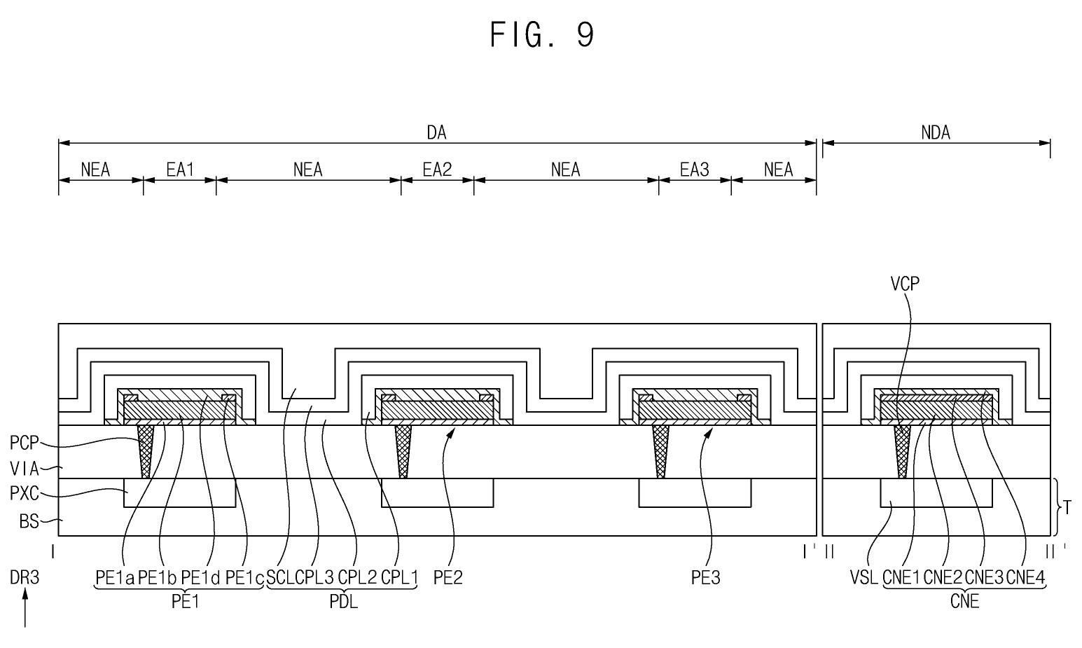

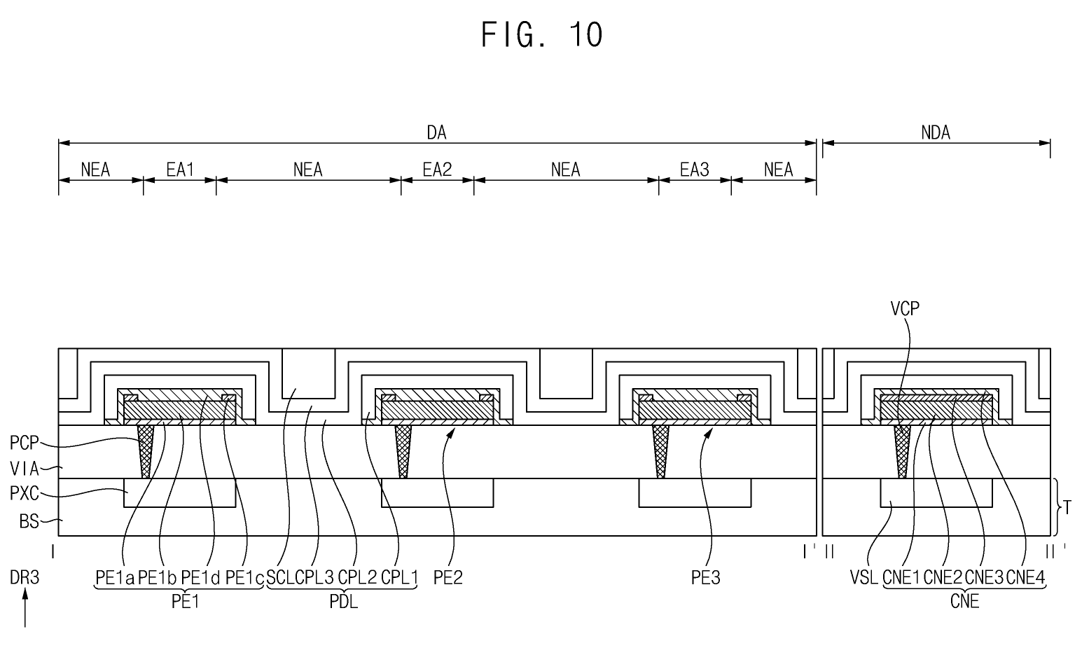

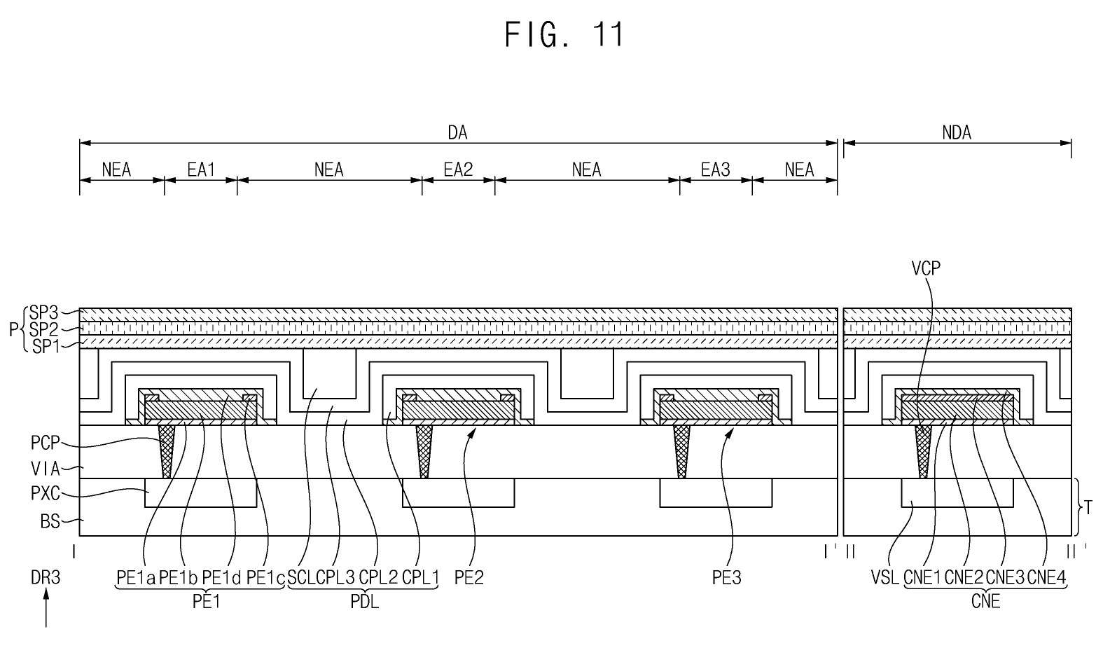

In an embodiment, the third capping layer CPL3 may include an inorganic insulating material. For example, the third capping layer CPL3 may include a different material from the first capping layer CPL1 and the second capping layer CPL2. For example, the third capping layer CPL3 may include silicon nitride (SiNₓ), but example embodiments are not limited thereto. The third capping layer CPL3 may function as a stopper for the step compensation layer SCL during a chemical mechanical polishing (“CMP”) process (see FIGS. 9 and 10).

A capping structure in which the first to third capping layers CPL1, CPL2, and CPL3 are stacked may define the first emission openings EO1. In an embodiment, a side surface of the first capping layer CPL1, a side surface of the second capping layer CPL2, and a side surface of the third capping layer CPL3 defining one of the first emission openings EO1 may be aligned with each other.

The step compensation layer SCL may be disposed on the third capping layer CPL3. The step compensation layer SCL may compensate for a step difference of the capping structure caused by the first to third pixel electrodes PE1, PE2, and PE3. The step compensation layer SCL may substantially planarize an upper surface of the pixel defining layer PDL in the non-display area NEA.

In an embodiment, the step compensation layer SCL may include an organic insulating material. For example, the step compensation layer SCL may include tetraethyl orthosilicate (“TEOS”), but example embodiments are not limited thereto.

The separator SP may be disposed on the pixel defining layer PDL. The separator SP may be disposed in the non-emission area NEA. The separator SP may define second emission openings EO2 respectively corresponding to the first to third emission areas EA1, EA2, and EA3. Each of the second emission openings EO2 may be connected to corresponding one of the first emission openings EO1. For example, a width of each of the second emission openings EO2 may be greater than a width of the corresponding one of the first emission openings EO1.

The separator SP may be configured to separate first to third charge generation layers CGL1, CGL2, and CGL3 respectively disposed in the first to third emission areas EA1, EA2, and EA3. In an embodiment, the separator SP may include a first insulating layer SP1, a second insulating layer SP2, and a third insulating layer SP3 that are sequentially stacked.

In an embodiment, each of the first to third insulating layers SP1, SP2, and SP3 may include an inorganic insulating material. The second insulating layer SP2 and the third insulating layer SP3 may include different materials. For example, the first insulating layer SP1 and the third insulating layer SP3 may include SiOₓ, and the second insulating layer SP2 may include SiNₓ, but example embodiments are not limited thereto.

In the display area DA, the separator SP may have an undercut structure in order to separate the first to third charge generation layers CGL1, CGL2, and CGL3 from each other. For example, as illustrated in FIG. 2, in the display area DA, a width of the second insulating layer SP2 may be less than a width of the third insulating layer SP3. In the display area DA, the second insulating layer SP2 may not cover a portion of a lower surface of the third insulating layer SP3. A side surface SP3_s of the third insulating layer SP3 defining one of the second emission openings EO2 may protrude from a side surface SP2_s of the second insulating layer SP2 defining the one of the second emission openings EO2 toward a center of the one of the second emission openings EO2.

The first to third emission layers EL1, EL2, and EL3 may be disposed to respectively correspond to the first to third emission areas EA1, EA2, and EA3. The first to third emission layers EL1, EL2, and EL3 may be respectively disposed in the first emission openings EO1 of the pixel defining layer PDL. The first to third emission layers EL1, EL2, and EL3 may respectively contact the first to third pixel electrodes PE1, PE2, and PE3.

In an embodiment, each of the first to third emission layers EL1, EL2, and EL3 may include a lower emission layer, a charge generation layer, and an upper emission layer that are stacked in the third direction DR3. For example, each of the first to third emission layers EL1, EL2, and EL3 may have a two-stack tandem structure. FIG. 2 illustrates that each of the first to third emission layers EL1, EL2, and EL3 has a two-stack tandem structure including two emission layers and one charge generation layer, example embodiments are not limited thereto, and each of the first to third emission layers EL1, EL2, and EL3 may have a tandem structure of three or more stacks.

The first emission layer EL1 may include a first lower emission layer EL1a, the first charge generation layer CGL1, and a first upper emission layer EL1b that are stacked in the third direction DR3. The second emission layer EL2 may include a second lower emission layer EL2a, the second charge generation layer CGL2, and a second upper emission layer EL2b that are stacked in the third direction DR3. The third emission layer EL3 may include a third lower emission layer EL3a, the third charge generation layer CGL3, and a third upper emission layer EL3b that are stacked in the third direction DR3.

In an embodiment, each of the first to third lower emission layers EL1a, EL2a, and EL3a and the first to third upper emission layers EL1b, EL2b, and EL3b may include an organic emission layer including an organic emission material and an auxiliary layer. The auxiliary layer may include at least one of a hole injection layer, a hole transport layer, an electron transport layer, or an electron injection layer.

In an embodiment, the first to third emission layers EL1, EL2, and EL3 may emit light of different colors. For example, the first emission layer EL1 may emit red light, the second emission layer EL2 may emit green light, and the third emission layer EL3 may emit blue light. In this case, each of the first lower emission layer EL1a and the first upper emission layer EL1b may include a red organic emission layer that emits red light, each of the second lower emission layer EL2a and the second upper emission layer EL2b may include a green organic emission layer that emits green light, and each of the third lower emission layer EL3a and the third upper emission layer EL3b may include a blue organic emission layer that emits blue light. For example, the organic emission layers included in the first to third lower emission layers EL1a, EL2a, and EL3a and the first to third upper emission layers EL1b, EL2b, and EL3b may be formed in corresponding ones of the first to third emission areas EA1, EA2, and EA3, respectively, using a deposition mask (e.g., a fine metal mask (“FMM”)).

In another embodiment, each of the first to third emission layers EL1, EL2, and EL3 may emit white light. In this case, each of the first to third lower emission layers EL1a, EL2a, and EL3a may include a blue organic emission layer that emits blue light, and each of the first to third upper emission layers EL1b, EL2b, and EL3b may include a yellow-green organic emission layer that emits yellow-green light. For example, the organic emission layers included in the first to third lower emission layers EL1a, EL2a, and EL3a and the first to third upper emission layers EL1b, EL2b, and EL3b may be entirely formed in the display area DA.

In an embodiment, at least some of the auxiliary layers included in the first to third lower emission layers EL1a, EL2a, and EL3a and the first to third upper emission layers EL1b, EL2b, and EL3b may be entirely formed in the display area DA.

The first charge generation layer CGL1 may be disposed between the first lower emission layer EL1a and the first upper emission layer EL1b. The first charge generation layer CGL1 may include an n-type charge generation layer for providing electrons to the first lower emission layer EL1a and a p-type charge generation layer for providing holes to the first upper emission layer EL1b.

The second charge generation layer CGL2 may be disposed between the second lower emission layer EL2a and the second upper emission layer EL2b. The second charge generation layer CGL2 may include an n-type charge generation layer for providing electrons to the second lower emission layer EL2a and a p-type charge generation layer for providing holes to the second upper emission layer EL2b.

The third charge generation layer CGL3 may be disposed between the third lower emission layer EL3a and the third upper emission layer EL3b. The third charge generation layer CGL3 may include an n-type charge generation layer for providing electrons to the third lower emission layer EL3a and a p-type charge generation layer for providing holes to the third upper emission layer EL3b.

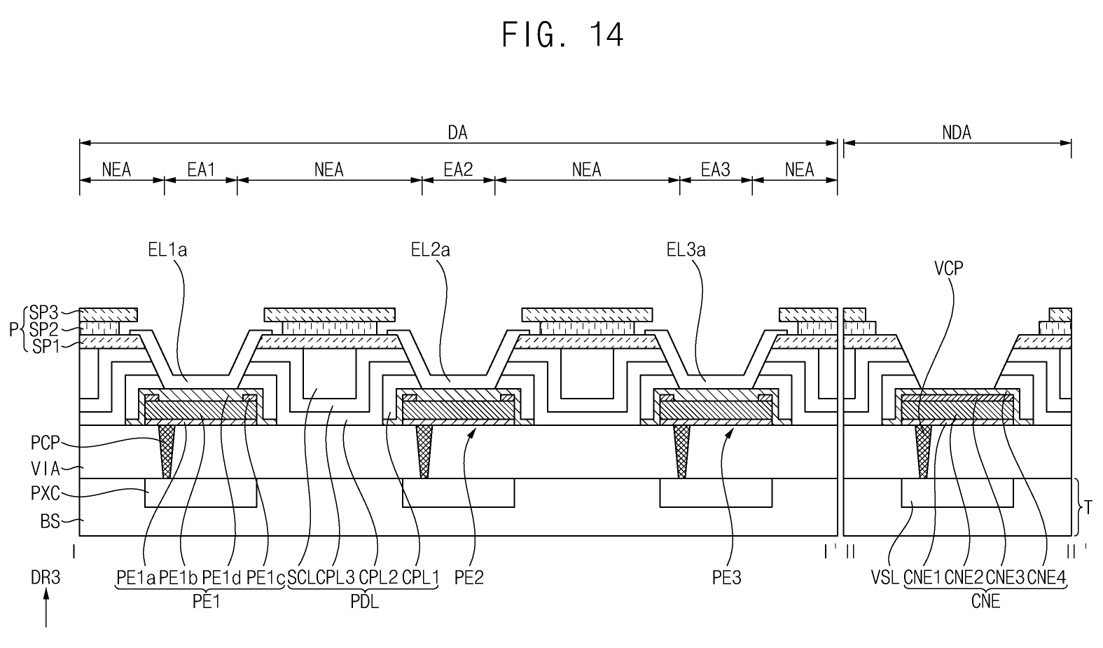

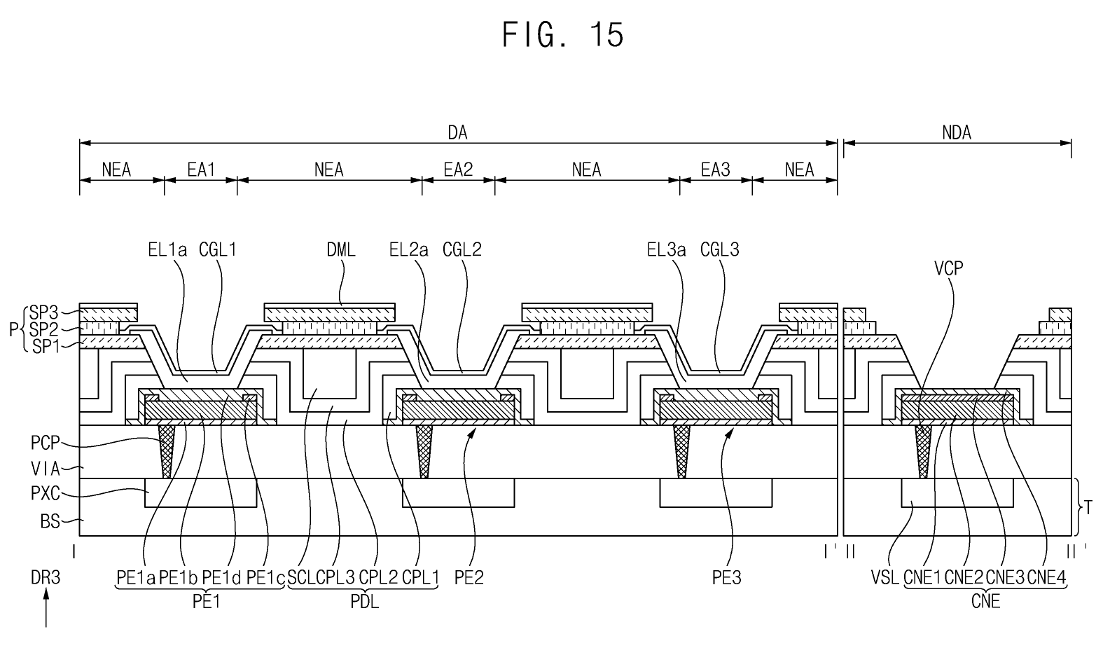

The first to third charge generation layers CGL1, CGL2, and CGL3 may be separated (i.e., electrically isolated or disconnected) from each other by the undercut structure of the separator SP. In this case, a dummy layer DML may be disposed on the third layer SP3 of the separator SP. The dummy layer DML may include the same material as the first to third charge generation layers CGL1, CGL2, and CGL3. Because the separator SP has the undercut structure, the first to third charge generation layers CGL1, CGL2, and CGL3 and the dummy layer DML may be formed to be separated (i.e., electrically isolated or disconnected) from each other (see FIGS. 14 and 15). Accordingly, leakage current between the adjacent light emitting elements LE1, LE2, and LE3 may be prevented or reduced, and the display quality of the display device DD may be improved.

When the first to third lower emission layers EL1a, EL2a, and EL3a and the first to third upper emission layers EL1b, EL2b, and EL3b are entirely formed in the display area DA, a first dummy layer, a second dummy layer, and a third dummy layer may be sequentially disposed on the third layer SP3 of the separator SP. The first dummy layer may include the same material as the first to third lower emission layers EL1a, EL2a, and EL3a. The second dummy layer may include the same material as the first to third charge generation layers CGL1, CGL2, and CGL3. The third dummy layer may include the same material as the first to third upper emission layers EL1b, EL2b, and EL3b.

The common electrode CE may be disposed on the first to third emission layers EL1, EL2, and EL3 and the separator SP. The common electrode CE may be entirely disposed in the display area DA. In an embodiment, the common electrode CE may have a light transmitting characteristic. That is, the common electrode CE may be a transparent electrode, and each of the first to third light emitting elements LE1, LE2, and LE3 may have a non-resonant structure. In the first to third emission areas EA1, EA2, and EA3, a distance between a reflective electrode (e.g., the second layer PE1b of the first pixel electrode PE1) of each of the first to third pixel electrodes PE1, PE2, and PE3 and the common electrode CE may be constant. Because each of the first to third light emitting elements LE1, LE2, and LE3 may have a non-resonant structure, variations in display quality depending on the viewing angle may be reduced.

FIG. 4 is a cross-sectional view taken along line II-II’ of FIG. 1.

Referring to FIGS. 1 and 4, in an embodiment, the display device DD may further include a common voltage supply line VSL, a voltage connection pattern VCP, and a connection electrode CNE disposed in the non-display area NDA.

The common voltage supply line VSL may be disposed in the non-display area NDA. For example, the common voltage supply line VSL may at least partially surround the display area DA in a plan view. A common voltage may be applied to the common voltage supply line VSL from a power module. The common voltage supply line VSL may supply the common voltage to the common electrode CE. The common voltage may be a low power supply voltage.

A second through hole that penetrates the via insulation layer VIA in the third direction DR3 may be defined in the via insulation layer VIA in the non-display area NDA. The second through hole may correspond to the common voltage supply line VSL.

The voltage connection pattern VCP may be disposed in the second through hole of the via insulating layer VIA in the non-display area NDA. The voltage connection pattern VCP may be electrically connected to the common voltage supply line VSL. The voltage connection pattern VCP may include a conductive material, such as W.

The connection electrode CNE may be disposed in the non-display area NDA on the via insulating layer VIA. The connection electrode CNE may be disposed corresponding to the voltage connection pattern VCP. The connection electrode CNE may be electrically connected to the common voltage supply line VSL through the voltage connection pattern VCP.

The connection electrode CNE may have a multi-layer structure. In an embodiment, the connection electrode CNE may include a first layer CNE1, a second layer CNE2, a third layer CNE3, and a fourth layer CNE4.

The first layer CNE1 may be disposed on the via insulating layer VIA. The first layer CNE1 may be electrically connected to the common voltage supply line VSL through the voltage connection pattern VCP. For example, a lower surface of the first layer CNE1 may contact an upper surface of the common voltage supply line VSL. For example, the lower surface of the first layer CNE1 may directly contact the upper surface of the common voltage supply line VSL.

The first layer CNE1 of the connection electrode CNE may include the same material as the first layer PE1a of the first pixel electrode PE1 of FIG. 2, and may be substantially simultaneously formed with the first layer PE1a of the first pixel electrode PE1. The first layer CNE1 may include the first conductive material.

The second layer CNE2 may be disposed on the first layer CNE1. For example, the second layer CNE2 may be disposed directly on the first layer CNE1. For example, a lower surface of the second layer CNE2 may contact an entire upper surface of the first layer CNE1. For example, the lower surface of the second layer CNE2 may directly contact the entire upper surface of the first layer CNE1.

The second layer CNE2 of the connection electrode CNE may include the same material as the second layer PE1b of the first pixel electrode PE1 of FIG. 2, and may be substantially simultaneously formed with the second layer PE1b of the first pixel electrode PE1. The second layer CNE2 may include the second conductive material.

The third layer CNE3 may be disposed on the second layer CNE2. For example, the third layer may can be disposed directly on the second layer CNE2. As illustrated in FIG. 4, the third layer CNE3 may cover an entire upper surface of the second layer CNE2. Because the second layer CNE2 of the connection electrode CNE disposed in the non-display area NDA does not function as a reflective electrode, the third layer CNE3 may cover the entire upper surface of the second layer CNE2. In an embodiment, a side surface of the first layer CNE1, a side surface of the second layer CNE2, and a side surface of the third layer CNE3 may be aligned with each other.

The third layer CNE3 of the connection electrode CNE may include the same material as the third layer PE1c of the first pixel electrode PE1 of FIG. 2, and may be substantially simultaneously formed with the third layer PE1c of the first pixel electrode PE1. The third layer CNE3 may include the third conductive material.

The fourth layer CNE4 may be disposed on the third layer CNE3. For example, the fourth layer CNE4 may be disposed directly on the third layer CNE3. In an embodiment, the fourth layer CNE4 may entirely cover a structure in which the first layer CNE1, the second layer CNE2, and the third layer CNE3 are stacked. The fourth layer CNE4 may contact the side surface of the first layer CNE1, the side surface of the second layer CNE2, the side surface of the third layer CNE3, and an upper surface of the third layer CNE3. For example, the fourth layer CNE4 may directly contact the side surface of the first layer CNE1, the side surface of the second layer CNE2, the side surface of the third layer CNE3, and the upper surface of the third layer CNE3.

The fourth layer CNE4 of the connection electrode CNE may include the same material as the fourth layer PE1d of the first pixel electrode PE1 of FIG. 2, and may be substantially simultaneously formed with the fourth layer PE1d of the first pixel electrode PE1. The fourth layer CNE4 may include the fourth conductive material.

The pixel defining layer PDL may also be disposed in the non-display area NDA. In the non-display area NDA, the pixel defining layer PDL may define a first connection opening CO1 that is positioned on the connection electrode CNE and exposes at least a portion of the connection electrode CNE.

The separator SP may also be disposed in the non-display area NDA. In the non-display area NDA, the separator SP may define a second connection opening CO2 that is positioned on the connection electrode CNE and the first connection opening CO1 and exposes at least a portion of the connection electrode CNE. The second connection opening CO2 may be connected to the first connection opening CO1.

Unlike the display area DA, in the non-display area NDA, the separator SP may not have an undercut structure. For example, as illustrated in FIG. 4, in the non-display area NDA, a width of the second insulating layer SP2 may be greater than a width of the third insulating layer SP3. In the non-display area NDA, the third insulating layer SP3 may not cover a portion of an upper surface of the second insulating layer SP2. A side surface SP2_s of the second insulating layer SP2 defining the second connection opening CO2 may protrude from a side surface SP3_s of the third insulating layer SP3 defining the second connection opening CO2 toward a center of the second connection opening CO2.

The common electrode CE may also be disposed in the non-display area NDA. In the non-display area NDA, the common electrode CE may be connected to the connection electrode CNE through the second connection opening CO2 of the separator SP and the first connection opening CO1 of the pixel defining layer PDL. Accordingly, the common electrode CE may be electrically connected to the common voltage supply line VSL through the connection electrode CNE and the voltage connection pattern VCP. Therefore, the common voltage may be transmitted to the common electrode CE.

Unlike the display area DA, the first to third emission layers EL1, EL2, and EL3 may not be disposed in the non-display area NDA. Therefore, if the separator SP has an undercut structure even in the non-display area NDA, the common electrode CE may be separated (i.e., electrically isolated or disconnected) by the separator SP in the non-display area NDA. According to embodiments, unlike the display area DA, the separator SP may not have an undercut structure in the non-display area NDA. Therefore, the common electrode CE may not be separated by the separator SP in the non-display area NDA.

According to embodiments, variations in display quality depending on the viewing angle may be reduced, and thus the display quality of the display device DD may be improved. In addition, the connection failure between the pixel circuit PXC and the transparent electrode of the pixel electrode may be prevented or reduced, and thus the reliability and yield of the display device DD may be improved.

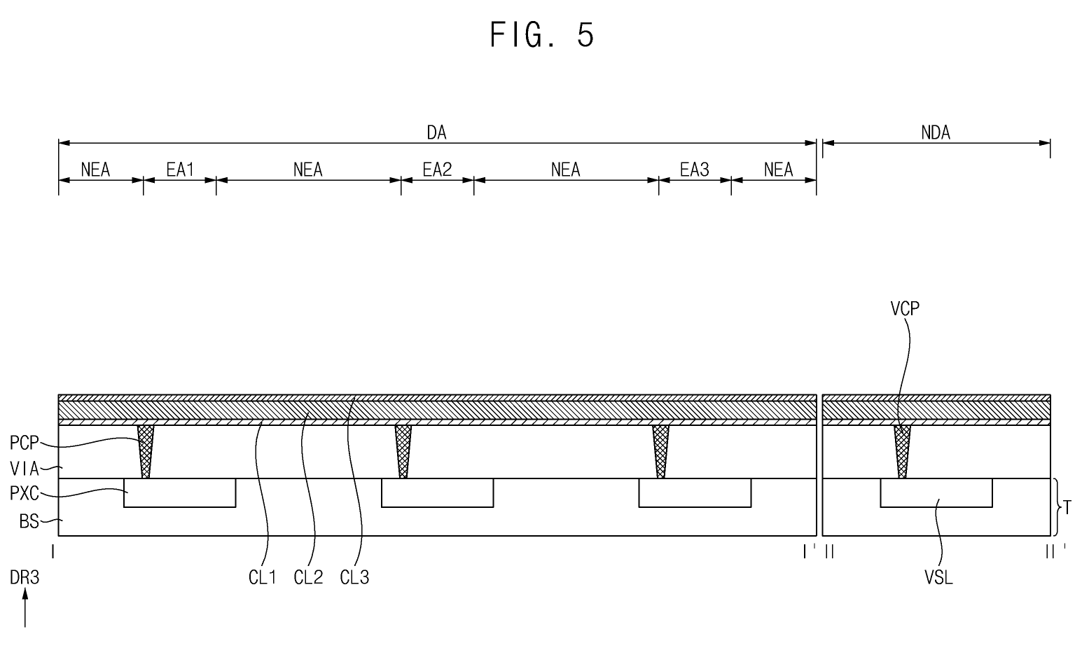

FIGS. 5-16 are cross-sectional views illustrating a method of manufacturing a display device according to an embodiment.

Hereinafter, an example of a method of manufacturing the display device DD of FIGS. 2-4 will be described with reference to FIGS. 5-16, and repeated description will be omitted or simplified.

Referring to FIG. 5, the transistor array substrate TAS including the base substrate BS, the pixel circuits PXC, and the common voltage supply line VSL may be formed. The base substrate BS may include the display area DA and the non-display area NDA. The display area DA may include the first to third emission areas EA1, EA2, and EA3 and the non-emission area NEA. The pixel circuits PXC may be formed in the display area DA, and the common voltage supply line VSL may be formed in the non-display area NDA.

The via insulating layer VIA may be formed by providing an organic insulating material on the transistor array substrate TAS. The via insulating layer VIA may be partially etched to form the first through holes in the display area DA and the second through hole in the non-display area NDA.

The pixel connection patterns PCP and the voltage connection pattern VCP may be formed by providing a conductive material in the first through holes and the second through hole of the via insulating layer VIA. The pixel connection patterns PCP may be respectively disposed in the first through holes of the via insulating layer VIA in the display area DA. The voltage connection pattern VCP may be disposed in the second through hole of the via insulating layer VIA in the non-display area NDA.

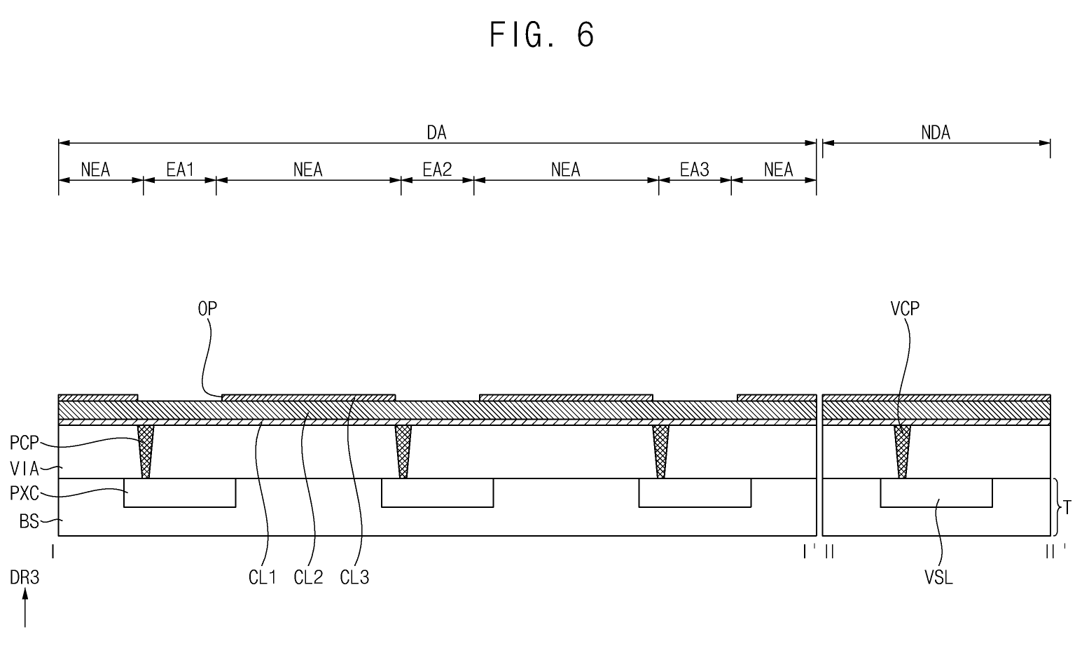

Referring further to FIGS. 6-8, the first to third pixel electrodes PE1, PE2, and PE3 and the connection electrode CNE may be formed on the via insulating layer VIA. The first to third pixel electrodes PE1, PE2, and PE3 may be formed respectively corresponding to the pixel connection patterns PCP in the display area DA, and the connection electrode CNE may be formed corresponding to the voltage connection pattern VCP in the non-display area NDA.

As illustrated in FIG. 5, a first conductive layer CL1, a second conductive layer CL2, and a third conductive layer CL3 may be sequentially formed on the via insulating layer VIA, the pixel connection patterns PCP, and the voltage connection pattern VCP. Each of the first to third conductive layers CL1, CL2, and CL3 may be entirely formed in the display area DA and the non-display area NDA.

The first conductive layer CL1 may include the first conductive material. In an embodiment, the first conductive material may include a metal or an alloy. For example, the first conductive material may include (or may be) Ti, but example embodiments are not limited thereto.

The second conductive layer CL2 may include the second conductive material. The second conductive material may have a light reflecting characteristic. In an embodiment, the second conductive material may include a metal or an alloy. For example, the second conductive material may include (or may be) Al or an Al alloy (e.g., an aluminum-copper alloy), but example embodiments are not limited thereto.

The third conductive layer CL3 may include the third conductive material. The light reflectance of the third conductive material may be less than the light reflectance of the second conductive material. In an embodiment, the third conductive material may include a metal nitride. The third conductive material may not include a metal oxide. For example, the third conductive material may include (or may be) TiNₓ, but example embodiments are not limited thereto.

As illustrated in FIG. 6, the third conductive layer CL3 may be partially etched to form openings OP respectively corresponding to the first to third emission areas EA1, EA2, and EA3. At this time, the openings OP may not be formed in the non-display area NDA. That is, the third conductive layer CL3 may not be etched in the non-display area NDA. For example, the third conductive layer CL3 may continuously extend and completely cover the second conductive layer CL2 in the non-display area NDA.

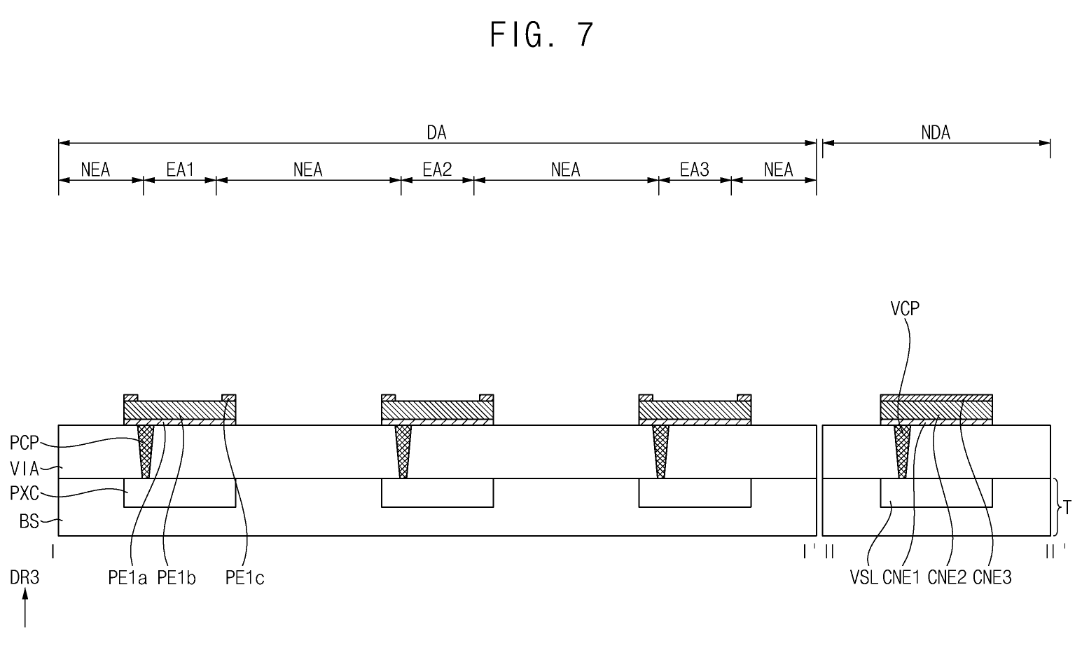

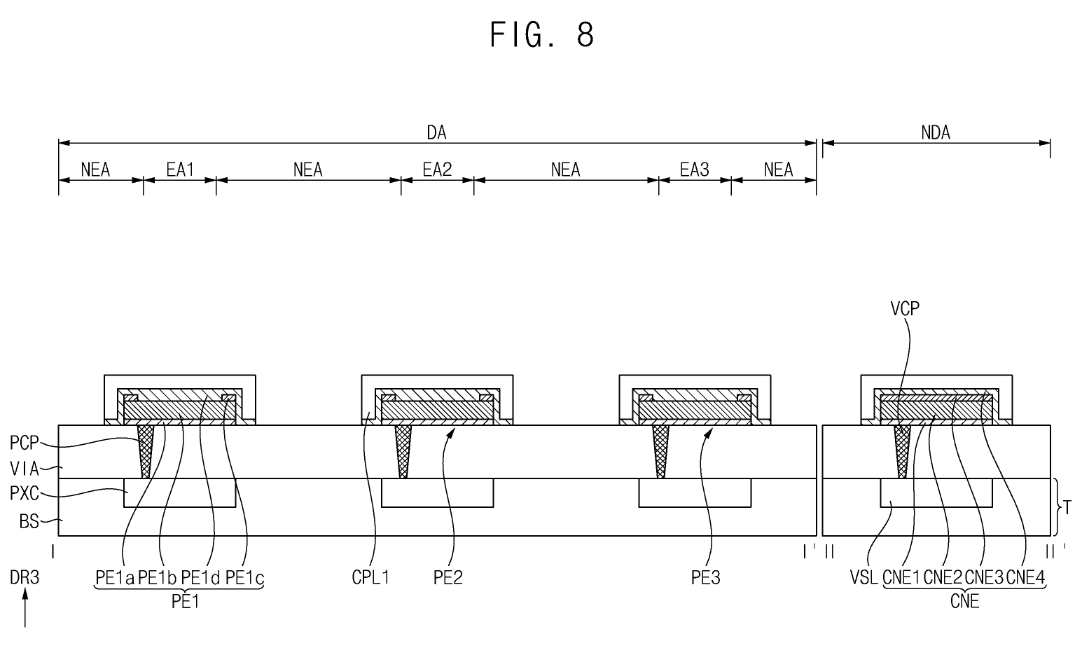

As illustrated in FIG. 7, the first to third layers PE1a, PE1b, and PE1c of the first pixel electrode PE1, the first to third layers of the second pixel electrode PE2, the first to third layers of the third pixel electrode PE3, and the first to third layers CNE1, CNE2, and CNE3 of the connection electrode CNE (see FIG. 8) may be formed by partially etching the first to third conductive layers CL1, CL2, and CL3. For example, the first to third conductive layers CL1, CL2, and CL3 may be etched by the same etching process, but example embodiments are not limited thereto. Among the first to third conductive layers CL1, CL2, and CL3, portions corresponding to the first emission area EA1, portions corresponding to the second emission area EA2, portions corresponding to the third emission area EA3, and a portion corresponding to a portion of the non-display area NDA (a portion connected to the voltage connection pattern VCP) may not be etched.

As illustrated in FIG. 8, the fourth layer PE1d of the first pixel electrode PE1, the fourth layer of the second pixel electrode PE2, the fourth layer of the third pixel electrode PE3, and the fourth layer CNE4 of the connection electrode CNE may be formed. The fourth layer PE1d of the first pixel electrode PE1 may be formed to entirely cover the first to third layers PE1a, PE1b, and PE1c of the first pixel electrode PE1. The fourth layer of the second pixel electrode PE2 may be formed to entirely cover the first to third layers of the second pixel electrode PE2. The fourth layer of the third pixel electrode PE3 may be formed to entirely cover the first to third layers of the third pixel electrode PE3. The fourth layer CNE4 of the connection electrode CNE may be formed to entirely cover the first to third layers CNE1, CNE2, and CNE3 of the connection electrode CNE.

For example, a fourth conductive layer including the fourth conductive material may be formed on the third layers PE1c and CNE3, and the fourth conductive layer may be partially etched to form the fourth layers PE1d and CNE4 spaced apart from each other.

The fourth conductive layer may include the fourth conductive material. The fourth conductive material may have a light transmitting characteristic. For example, the fourth conductive material may include (or may be) ITO, IZO, ZnOₓ, InOₓ, IGO, AZO, or the like, but example embodiments are not limited thereto.

The first capping layers CPL1 respectively covering the first to third pixel electrodes PE1, PE2, and PE3 and the connection electrode CNE may be formed. For example, a first inorganic layer may be formed on the fourth conductive layer, and the first inorganic layer may be partially etched to form the first capping layers CPL1 spaced apart from each other. For example, the first inorganic layer and the fourth conductive layer may be etched by the same etching process, but example embodiments are not limited thereto.

Referring to FIG. 9, the second capping layer CPL2, the third capping layer CPL3, and the step compensation layer SCL may be formed on the first capping layers CPL1 to form the pixel defining layer PDL. The step compensation layer SCL may compensate for the step difference of the first to third capping layers CPL1, CPL2, and CPL3 caused by the first to third pixel electrodes PE1, PE2, and PE3.

Referring to FIG. 10, an upper portion of the step compensation layer SCL may be removed by a CMP process. The third capping layer CPL3 may function as a stopper for the step compensation layer SCL during the CMP process.

Referring to FIGS. 11-13, the separator SP may be formed on the pixel defining layer PDL. The separator SP may include first to third insulating layers SP1, SP2, and SP3.

As illustrated in FIG. 11, the first to third insulating layers SP1, SP2, and SP3 may be entirely formed in the display area DA and the non-display area NDA. In an embodiment, each of the first to third insulating layers SP1, SP2, and SP3 may include an inorganic insulating material. The second insulating layer SP2 and the third insulating layer SP3 may include different materials. For example, the first insulating layer SP1 and the third insulating layer SP3 may include SiOₓ, and the second insulating layer SP2 may include SiNₓ, but example embodiments are not limited thereto.

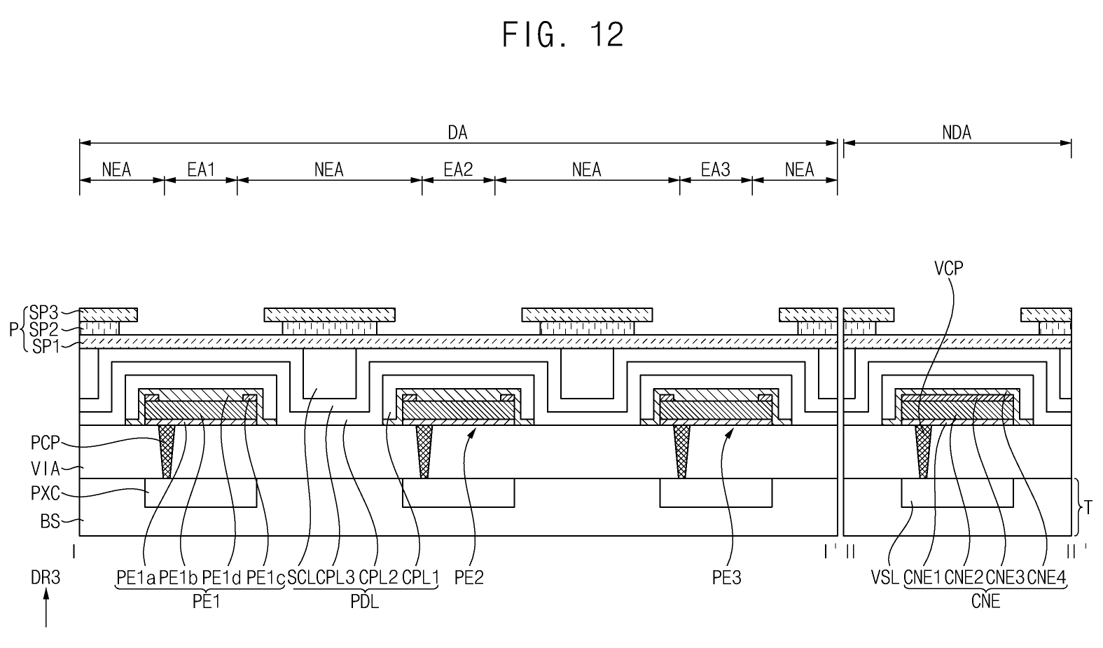

As illustrated in FIG. 12, the second insulating layer SP2 and the third insulating layer SP3 may be partially etched. At this time, in the first to third emission areas EA1, EA2, and EA3 of the display area DA and a portion of the non-display area NDA (on the connection electrode CNE), the second insulating layer SP2 may be etched to have an undercut structure with respect to the third insulating layer SP3.

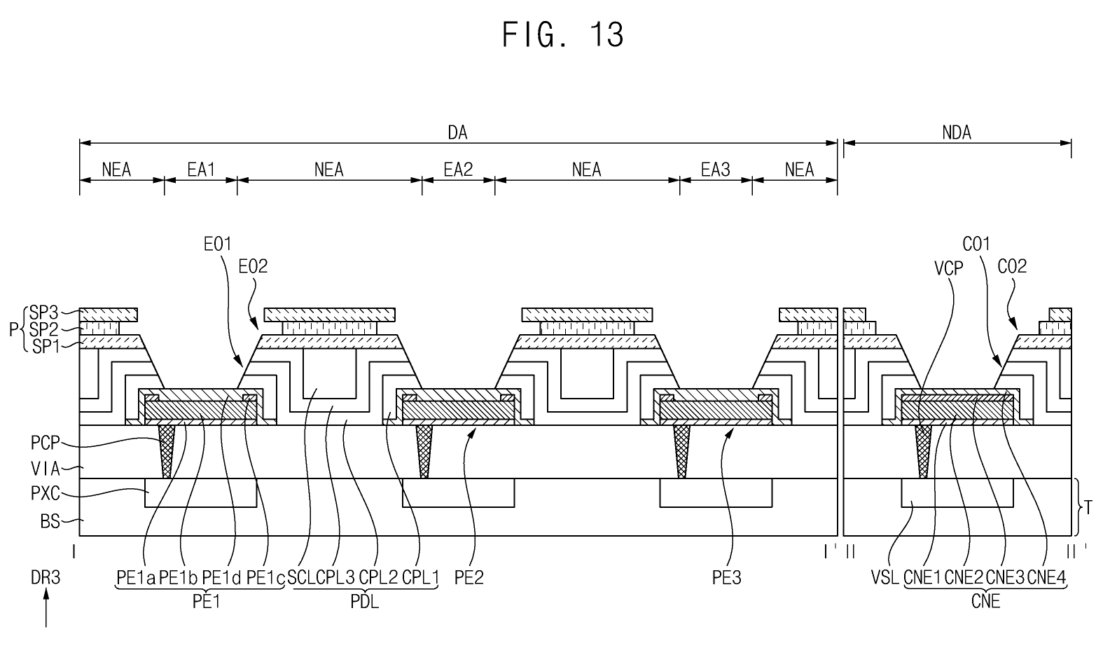

As illustrated in FIG. 13, the first to third capping layers CPL1, CPL2, and CPL3 of the pixel defining layer PDL and the first insulating layer SP1 of the separator SP may be partially etched to form the first emission opening EO1, the first connection opening CO1, the second emission opening EO2, and the second connection opening CO2. For example, the first to third capping layers CPL1, CPL2, and CPL3 and the first insulating layer SP1 may be etched by the same etching process, but example embodiments are not limited thereto. At this time, the third insulating layer SP3 may not be etched in the display area DA, but a portion of the third insulating layer SP3 may be etched together in the non-display area NDA. Accordingly, a portion of the separator SP defining the second emission opening EO2 in the display area DA may be formed to have an undercut structure, while another portion of the separator SP defining the second connection opening CO2 in the non-display area NDA may be formed to not have an undercut structure.

Referring to FIG. 14, first to third lower emission layers EL1a, EL2a, and EL3a may be formed in the display area DA. The first to third lower emission layers EL1a, EL2a, and EL3a may not be formed in the non-display area NDA. For example, the organic emission layers included in the first to third lower emission layers EL1a, EL2a, and EL3a may be formed in corresponding ones of the first to third emission areas EA1, EA2, and EA3, respectively, using a deposition mask. However, this is exemplary and example embodiments are not limited thereto.

Referring to FIG. 15, the first to third charge generation layers CGL1, CGL2, and CGL3 and the dummy layer DML may be formed in the display area DA. The first to third charge generation layers CGL1, CGL2, and CGL3 may not be formed in the non-display area NDA. In the display area DA, the first to third charge generation layers CGL1, CGL2, and CGL3 and the dummy layer DML may be separated (i.e., electrically isolated or disconnected) from each other by the undercut structure of the separator SP.

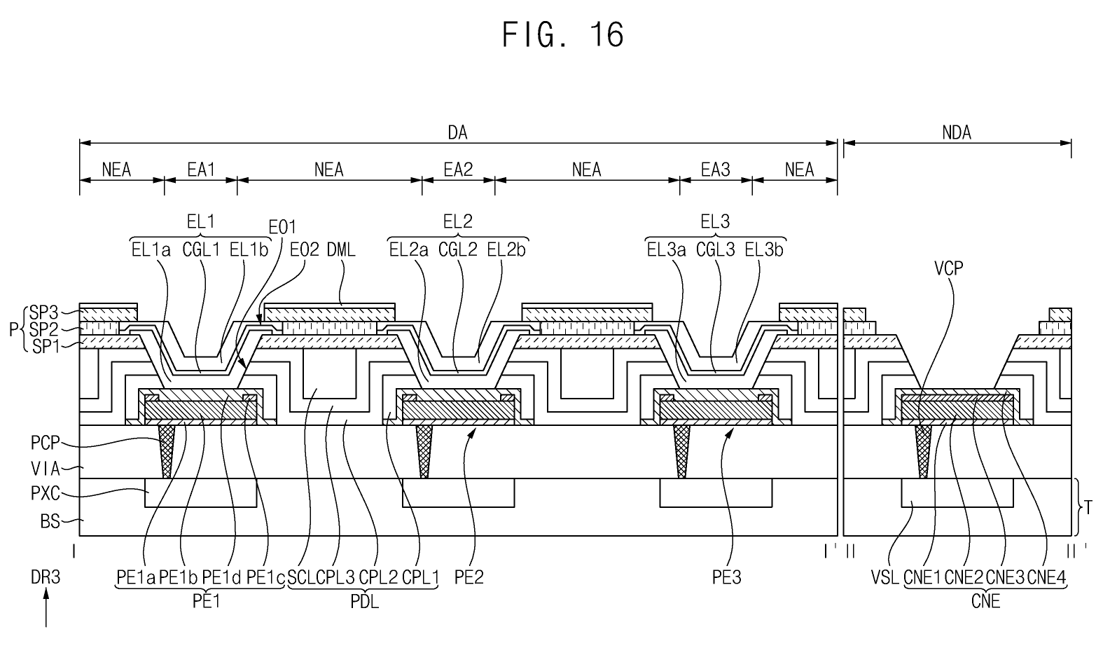

Referring to FIG. 16, first to third upper emission layers EL1b, EL2b, and EL3b may be formed in the display area DA. The first to third upper emission layers EL1b, EL2b, and EL3b may not be formed in the non-display area NDA. For example, the organic emission layers included in the first to third lower emission layers EL1b, EL2b, and EL3b may be formed in corresponding ones of the first to third emission areas EA1, EA2, and EA3, respectively, using a deposition mask. However, this is exemplary and example embodiments are not limited thereto.

As illustrated in FIGS. 2 and 4, the common electrode may can be formed on the first to third emission layers EL1, EL2, and EL3 and the separator SP. The common electrode CE may be entirely formed in the display area DA and the non-display area NDA.

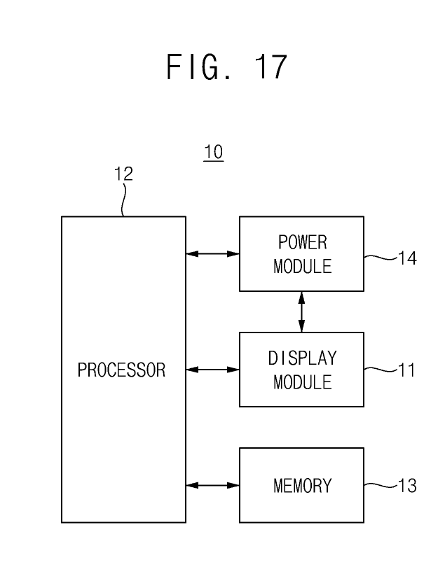

FIG. 17 is a block diagram illustrating an electronic device according to an embodiment.

Referring to FIG. 17, an electronic device 10 may include a display module 11, a processor 12, a memory 13, and a power module 14.

A display device according to embodiments (e.g., the display device DD of FIGS. 1-4) may be applied to various electronic devices 10. The electronic device 10 may include the display device described above, and may further include modules or devices with additional functions other than the display device.

The processor 12 may include at least one of a central processing unit (“CPU”), an application processor (“AP”), a graphic processing unit (“GPU”), a communication processor (“CP”), an image signal processor (“ISP”), and a controller. The processor 12 may control the display device.

The memory 15 may store data information necessary for the operation of the processor 12 or the display module 11. When the processor 12 executes the application stored in the memory 15, input image data and/or an input control signal may be transmitted to the display module 11, and the display module 11 may process the received signal and output image information through a display screen.

The power module 14 may include a power supply module (or power supply circuit), such as a power adapter or a battery device, and a power conversion module (or power conversion circuit) which converts the power supplied by the power supply module to generate power required for the operation of the electronic device 10.

At least one of each component of the electronic device 10 described above may be included in the display device according to embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

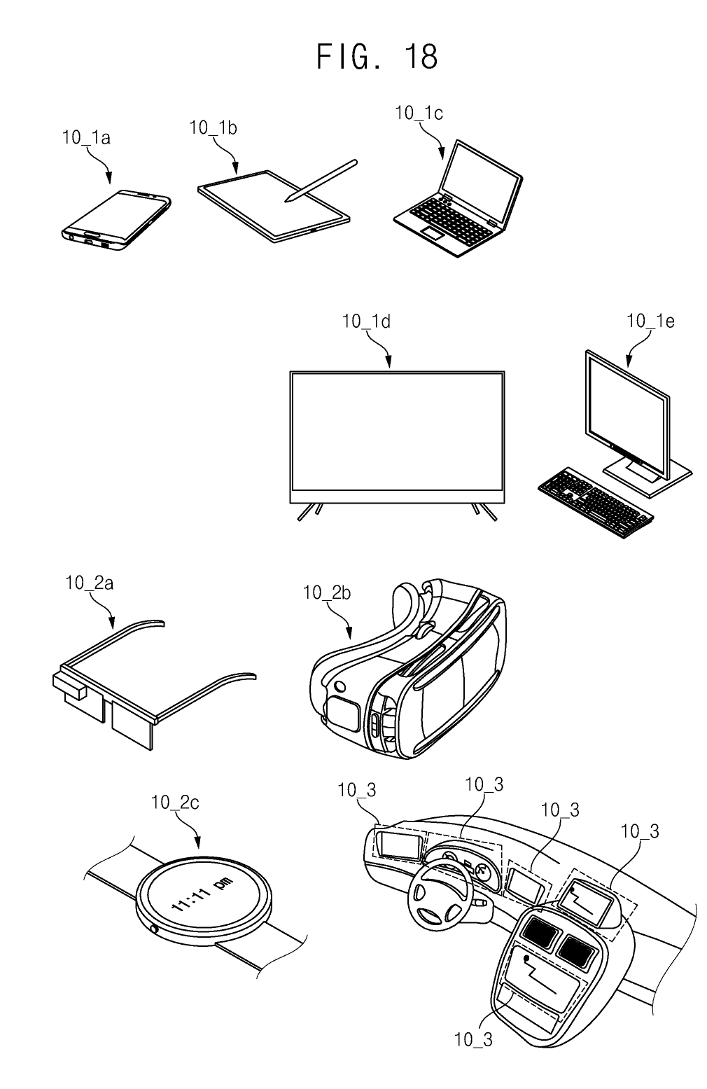

FIG. 18 are schematic diagrams illustrating an electronic device according to various embodiments.

Referring to FIGS. 17 and 18, various electronic devices 10 to which the display device according to embodiments are applied may include not only image display electronic devices such as a smartphone 10_1a, a tablet PC 10_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (“CID”) disposed on a dashboard, and a room mirror display, or the like.

While aspects of example embodiments have been particularly shown and described, it will be understood that various changes in form and details may be made therein without departing from the spirit and scope of the following claims.

What is claimed is:

1. A display device comprising:
a transistor array substrate comprising a display area and a non-display area outside the display area, wherein the display area comprises an emission area and a non-emission area, and the transistor array substrate comprises a pixel circuit in the display area;
a pixel electrode in the emission area on the transistor array substrate, wherein the pixel electrode comprises:
a first layer connected to the pixel circuit and comprising a first conductive material;
a second layer on the first layer and comprising a second conductive material;
a third layer on the second layer, wherein the third layer comprises a third conductive material, wherein the third layer is on an upper surface of an edge portion of the second layer, and wherein an opening that exposes an upper surface of a central portion of the second layer is defined in the third layer; and
a fourth layer on the second layer and the third layer and comprising a fourth conductive material;
an emission layer on the pixel electrode; and
a common electrode on the emission layer.

2. The display device of claim 1, wherein the second to fourth conductive materials are different from each other.

3. The display device of claim 1, wherein the second conductive material has a light reflecting characteristic, and
wherein the fourth conductive material has a light transmitting characteristic.

4. The display device of claim 3, wherein a light reflectance of the third conductive material is less than a light reflectance of the second conductive material.

5. The display device of claim 1, wherein the fourth layer contacts a side surface of the first layer, a side surface of the second layer, and a side surface of the third layer.

6. The display device of claim 5, wherein the fourth layer contacts an upper surface of the third layer and the upper surface of the central portion of the second layer exposed by the opening of the third layer.

7. The display device of claim 5, wherein the second conductive material comprises a metal or an alloy,
wherein the third conductive material comprises a metal nitride, and
wherein the fourth conductive material comprises a transparent conductive oxide.

8. The display device of claim 7, wherein the second conductive material comprises aluminum or an aluminum alloy,
wherein the third conductive material comprises titanium nitride, and
wherein the fourth conductive material comprises indium tin oxide.

9. The display device of claim 5, wherein the third layer comprises an inner side surface defining the opening and an outer side surface opposite to the inner side surface, and
wherein the fourth layer contacts the inner side surface of the third layer and the outer side surface of the third layer.

10. The display device of claim 9, wherein the side surface of the first layer, the side surface of the second layer, and the outer side surface of the third layer are coplanar.

11. The display device of claim 1, wherein the emission layer comprises a lower emission layer, a charge generation layer, and an upper emission layer that are sequentially stacked, and
wherein the emission area is one among a plurality of emission areas, and the charge generation layers respectively in the plurality of emission areas are separated from each other.

12. The display device of claim 11, wherein the common electrode has a light transmitting characteristic, and
wherein in the plurality of emission areas, a distance between the second layer of the pixel electrode and the common electrode is constant.

13. The display device of claim 11, further comprising:
a pixel defining layer defining first emission openings respectively corresponding to the plurality of emission areas; and
a separator structure on the pixel defining layer, defining second emission openings respectively corresponding to the plurality of emission areas, and separating the charge generation layers respectively in the plurality of emission areas from each other.

14. The display device of claim 13, wherein the separator structure comprises a first insulating layer, a second insulating layer, and a third insulating layer that are sequentially stacked, and the separator structure has an undercut structure in which a width of the second insulating layer is less than a width of the third insulating layer in the display area.

15. The display device of claim 14, wherein in the display area, a side surface of the third insulating layer defining one of the second emission openings protrudes from a side surface of the second insulating layer defining one of the second emission openings toward a center of the one of the second emission openings.

16. The display device of claim 14, further comprising:
a common voltage supply line in the non-display area; and
a connection electrode in the non-display area, wherein the connection electrode comprises:
a first connection layer connected to the common voltage supply line and comprising the first conductive material;
a second connection layer on the first connection layer and comprising the second conductive material;
a third connection layer on the second connection layer, wherein the third connection layer comprises the third conductive material, and covers an entire upper surface of the second connection layer; and
a fourth connection layer on the third connection layer and comprising the fourth conductive material.

17. The display device of claim 16, wherein the pixel defining layer defines a first connection opening on the connection electrode in the non-display area,
wherein the separator structure defines a second connection opening on the connection electrode in the non-display area, and
wherein the common electrode is connected to the connection electrode in the non-display area through the first connection opening and the second connection opening.

18. The display device of claim 17, wherein in the non-display area, a side surface of the second insulating layer defining the second connection opening protrudes from a side surface of the third insulating layer defining the second connection opening toward a center of the second connection opening.

19. A method of manufacturing a display device, the method comprising:
providing a transistor array substrate comprising a display area comprising an emission area and a non-emission area and a non-display area outside the display area, the transistor array substrate comprising a pixel circuit in the display area;
sequentially forming a first conductive layer, a second conductive layer, and a third conductive layer on the transistor array substrate;
partially etching the third conductive layer to form an opening corresponding to the emission area;
forming a first layer corresponding to the emission area, a second layer on the first layer, and a third layer covering an upper surface of an edge portion of the second layer by partially etching each of the first conductive layer and the second conductive layer, wherein the third layer defines an opening in the emission area that exposes an upper surface of a central portion of the second layer;
forming a fourth layer on the second and third layers to form a pixel electrode comprising the first to fourth layers;
forming an emission layer on the pixel electrode; and
forming a common electrode on the emission layer.

20. An electronic device comprising:
a display device configured to display an image; and
a processor configured to provide input image data and an input control signal to the display device,
wherein the display device comprises:
a transistor array substrate comprising a display area and a non-display area outside the display area, wherein the display area comprises an emission area and a non-emission area, and the transistor array substrate comprises a pixel circuit in the display area;
a pixel electrode in the emission area on the transistor array substrate, wherein the pixel electrode comprises:
a first layer connected to the pixel circuit and comprising a first conductive material;
a second layer on the first layer and comprising a second conductive material;
a third layer on the second layer, wherein the third layer comprises a third conductive material, wherein the third layer is on an upper surface of an edge portion of the second layer, and wherein an opening that exposes an upper surface of a central portion of the second layer is defined in the third layer; and
a fourth layer on the second layer and the third layer and comprising a fourth conductive material;
an emission layer on the pixel electrode; and
a common electrode on the emission layer.
